(19) United States
(12) Patent Application Publication
(10) Pub. No.: US 2009/0202738 A1
(43) Pub. Date: Aug. 13, 2009

(54) PROCESS FOR MAKING CAPACITORS BY DIRECT HEATING OF ELECTRODES

(75) Inventors: John Ege Anderson, Avondale, PA (US); Juan Carlos Figueroa, Wilmington, DE (US); John William Hoffman, SR., Oxford, PA (US); Damien Francis Reardon, Wilmington, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington (DE)

(21) Appl. No.: 12/367,795

(22) Filed: Feb. 9, 2009

Related U.S. Application Data
(60) Provisional application No. 61/028,235, filed on Feb. 13, 2008.

(51) Int. Cl. B05D 3/14; B05D 3/02; H01L 21/203

(52) U.S. Cl. 427/541; 427/545; 438/381

(57) ABSTRACT

Processes for manufacturing capacitors are provided. The processes include direct heating by passing a current through the metal foil substrate, which allows faster heating rates which in turn allow the growth of larger dielectric grains than obtained with conventional processes. Larger dielectric grains produce a capacitor with a higher specific capacitance.

### FIELD OF THE INVENTION

The present invention relates to processes for the manufacture of capacitors.

### TECHNICAL BACKGROUND

The manufacture of capacitors by chemical solution deposition on metal foils requires a step for the nucleation and growth of large grains to increase the dielectric constant of the dielectric.

Embedded capacitors are being developed by the semiconductor industry to address increasing demands for miniaturization and faster clock speeds. Such devices consist of a high permittivity dielectric layer sandwiched between a metal foil substrate electrode and a top metal layer electrode. The coating of the thin dielectric layer onto a metallic foil can be accomplished via reactive sputtering, laser ablation, metallo-organic chemical vapor deposition, liquid source misted chemical deposition, chemical solution deposition via spin coating or spraying or dipping, and others. In all cases, the deposited layer is thermochemically processed after deposition to improve the properties of the dielectric film.

Thermochemical processing of the precursor coatings is conventionally effected via indirect heating of the coated foil with external heating sources such as ovens. However, the maximum attainable heating rate is limited in indirect heating since the thermal mass of the heating sources and ancillary hardware, being substantially bigger than that of the coated foil, limits the attainable heating rate. This can affect the dynamics of nucleation and growth of crystalline dielectric grains, as faster heating rates reduce nucleation rates in favor of higher growth rates to yield larger grains.

The maximum attainable foil temperature may be limited by the materials of construction of the heating sources and ancillary hardware. These elements may limit the maximum operating temperature of the source, and therefore the maximum attainable temperature of the coated foil. In particular, lamps use transparent dielectric windows that can not be heated above specific maximum temperatures. Higher dielectric sintering temperatures facilitate improvements in grain size and quality of crystallinity, both factors determining attainment of high permitivities.

The coated foil temperature control can be cumbersome when using radiative heating sources, given that the fundamental parameters governing the heat exchange dynamics between the source and the coated foil constantly change. These include window transmission efficiency, coefficient of absorption of the coated foil and all surrounding hardware, etc. The foil temperature spatial uniformity is important. The heating sources can be inherently non-spatially uniform—like induction coils. Relative motion between the heating source and the coated foil is often used to attain improved spatial uniformity of the coated foil temperature.

Another concern is contamination. When the heating source materials of construction are exposed to the reaction atmosphere, they provide a potential source of contamination to the dielectric layer and the foil. The heating source materials of construction can degrade as a result of repeated heating cycles. Yet another concern is equipment complexity and cost. Indirect heating of foils can require complicated hardware that drives up the cost of the equipment.

U.S. Pat. No. 7,029,971 discloses a process for the production of barium titanate and doped barium titanate capacitors using chemical solution deposition and a reoxygenation step.

US Patent Publication No. 2007/0049026 discloses a process for the production of barium titanate capacitors using chemical solution deposition and a heat treatment in a reduced pressure environment.

The manufacture of barium titanate capacitors by chemical solution deposition on metal foils typically requires a heating step to crystallize the dielectric. The present inventors have found that direct heating by passing a current through the metal foil substrate allows faster heating rates which in turn allow the growth of larger dielectric grains. Larger dielectric grains produce a capacitor with a higher specific capacitance.

### BRIEF DESCRIPTION OF THE DRAWINGS

FIG. 1 shows a schematic description of a direct heating assembly.

### SUMMARY OF THE INVENTION

One aspect of the present invention is a process comprising:

a) providing a metal foil substrate;

b) depositing a layer of solution comprising a Ti chelate, a Ba chelate and a solvent on the metal foil substrate;

c) passing an electric current through the metal foil substrate to evaporate the solvent and burn out the organic ligands chelated to Ti and the organic ligands chelated to Ba to form a residual layer;

d) passing an electric current through the metal foil substrate to sinter the residual layer;

e) depositing a top electrode on the surface of the sintered layer.

Another aspect of the present invention is a process comprising:

a) providing a metal foil substrate;

b) vapor depositing a mixture comprising Ba and Ti oxides on the metal foil substrate;

c) passing an electric current through the metal foil substrate to heat the foil substrate to a temperature below the temperature of metal oxide formation during vapor deposition;

d) passing an electric current through the metal foil substrate to heat the foil substrate to a crystallization temperature for BaTiO3;

e) depositing a top electrode on the surface of the vapor deposited layer.

### DETAILED DESCRIPTION

The present invention provides a lower cost process, as compared to conventional processes, using direct heating of a self-supported metal foil substrate to process the deposited precursors of the dielectric of the capacitor. Direct heating enables higher heating rates, which increase the performance of the capacitor. Metal foil self-support enables attainment of higher soaking temperatures, lower surface contamination levels and higher cooling rates which also increase the performance of the capacitor.

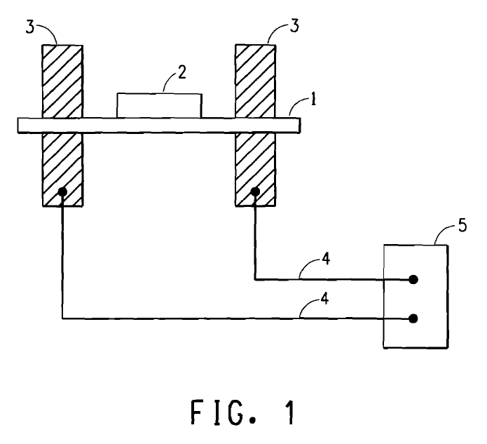

A device comprising two terminal blocks for holding and delivering electrical power to a coated foil that self-supports between the terminals enables the direct self-heating of the coated foil. An example of such a device according to one embodiment of the invention is shown in FIG. 1. In FIG. 1, the metal foil to be directly heated is shown as item 1. The metal foil is coated with the dielectric precursor 2. The metal foil may be mounted between a pair of electrical terminals 3 which are connected by electrical power leads 4 to a power supply 5.

The high aspect ratio of a coated foil (which is in the form of a sheet) facilitates retention of the resistively-produced heat due to the electrical current to attain exceedingly higher heating rates and temperatures than those attainable with indirect heating sources. Electrical power is delivered by any conventional power supply operating at any convenient frequency, such as, for example, 60 cycles per second. Such a device facilitates, better than indirect heating sources, the thermochemical processing of foils prior, during or after the coating of precursors via reactive sputtering, laser ablation, metallo-organic chemical vapor deposition, liquid source misted chemical deposition, chemical solution deposition via spin coating or spraying or dipping, and others. When using terminal blocks that have a much higher thermal mass (for example, the terminal blocks can have at least 100 times the thermal mass of the foil) than the coated foil and/or are water-cooled, much higher cooling rates are attained compared to those attained with indirect heating sources. Typically, direct heating has at least a five times faster cooling rate than indirect heating. A roll-to-roll thermochemical process requires less equipment using direct heating as compared to indirect heating.

Direct heating of metal foil substrates can reduce cycle time from 12 hours when using conventional quartz tube furnaces to less than 15 minutes. Direct heating can reduce contamination imparted by the materials of construction of the quartz tube furnace. Direct heating of barium titanate (BT)-precursor coated metal foils to synthesize high permittivity, low loss and highly resistive crackless BaTiO3 dielectric layers is demonstrated in the present invention. The dielectric displays excellent adhesion to the metal foil substrate as demonstrated by lack of defects observed in electron micrographs of the dielectric—foil interface. The directly-heated foil (DHF) technology enables attainment of flash heating rates in excess of 500° C./s and foil temperatures >1,100° C. which are not possible on reflective substrates with conventional, non convective RTA furnaces using radiative heat sources. Such process conditions uniquely facilitate solid state reaction pathways that enable synthesis of superior dielectric layers.

The metal foil may also comprise a layer deposited on the surface of the base metal, prior to deposition of the dielectric precursor layer, to act as a barrier during the processing of the dielectric precursor layer by blocking the diffusion of metal foil constituents and/or eliminating the formation of oxides that reduce the capacitance of the coated foil.

For the embodiment of the present invention where the metal foil is a nickel foil, deposition of a barium titanate dielectric thin film on a nickel foil to make a thin film capacitor with capacitance higher than 0.1 microfarads per square centimeter can be achieved through a physical vapor deposition process or a chemical solution deposition process. One contributing factor to higher capacitance is the absence of NiO at the interface between the metal and the dielectric material deposited (BaTiO3). Most conventional materials will have a native oxide layer on the surface which contributes to lowering the capacitance of the device as described by the following equation of capacitors in series:

1/Ctotal=1/C1+1/C2+1/C3+ . . . +1/Cn

where the total capacitance is dominated by the material with the lowest dielectric constant (NiO). By eliminating this undesired material the capacitance will then be dominated by the deposited barium titanate dielectric material. The physical vapor deposition process which sputters barium titanate onto the metal foil is void of organics and is therefore susceptible to further oxidation at higher temperatures during the firing process.

For chemical solution deposition process according to an embodiment of the present invention, precursor molecules are deposited on the surface of a nickel foil. The precursor molecules are carried in a solvent and contain ligands attached to the barium, titanium and any dopant constituent to be used with the barium titanate. Appropriate barium and titanium (IV) precursors are of the type:

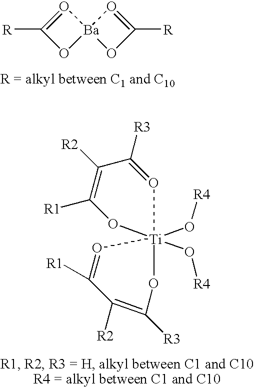

Suitable solvents for the deposition of these precursors include alcohols, carboxylic acids and mixtures of alcohols and carboxylic acids.

In order to obtain a uniform coating of the barium titanate precursor formulation on the nickel foil the surface of the foil is preferably degreased in an organic solvent such as acetone to increase wetting of the surface and maximize performance of the final capacitor device. The solution containing the precursor molecules and the solvent can be applied to the nickel foil by any known coating technique such as spin coating, immersion, or brushing doctor blades. Once the solution is coated on the foil, the solvent is removed through an evaporation process. This can be done by heating, for example, to 100° C. for a few minutes ranging from 1 to 60 minutes. Following the de-solvation of the deposited film, the organic ligands chelating the barium and titanium precursors are decomposed at a temperature of 250° C. to 400° C. for a time of about 1 to 60 minutes), leaving a deposit. The resulting deposit is substantially an amorphous inorganic precursor to barium titanate, which may be doped with other constituents such as strontium, Group II, Group III, transition metals or rare earths to achieve the desired dielectric properties and leakage current of the crystalline barium titanate.

Exposure of the nickel foil to temperatures above 400° C. for extended periods of time in air can lead to oxidation of the nickel. The resulting NiO formation would yield lower capacitance values, which is undesirable. The transformation of the amorphous, doped or non-doped, barium titanate to the crystalline state on nickel foil typically includes heating to higher temperatures under lower partial pressure of oxygen than in air. It is found that heating the amorphous barium titanate to temperatures >550° C. in an atmosphere with a oxygen partial pressure of 10⁻⁸ atm or less reduces the oxidation of the nickel foil for heating periods of between 10 seconds and 1 hour which is long enough to crystallize the barium titanate. However, heating the barium titanate in oxygen partial pressures less than 10⁻¹⁰ atmospheres introduces defects into the barium titanate which can increase the leakage current of the dielectric, making the capacitor undesirable. The leakage current can be reduced by a reoxygenation heat treatment, which is an additional process step. Reoxygenation treatment can be omitted when heat treatment is carried out in an atmosphere of 10⁻⁸ to 10⁻¹⁰ atmospheres of oxygen at 750° C. or above for 1 to 60 minutes.

After the barium titanate or doped barium titanate dielectric is crystallized, the second electrode can be deposited on the dielectric. The second electrode is a conductor such as, for example, copper, nickel, gold or Pt. The second electrode may be vapor deposited.

### EXAMPLES

### Example 1

In the following examples, a precursor 0.2 M formulation with respect to [Ti] was prepared in the following manner:

25.5100 g (89.99 mmol) of anhydrous barium propionate (synthesized according to Hasenkox, U.; Hoffmann, S.; Waser R.; Journal of Sol-Gel Science and Technology, 1998, 12, 67-79.) was dissolved in a minimum amount of propionic acid (60.00 ml). To this solution, was added 35.3100 g of bis(acetylacetonato)bis(butoxo)titanium (89.99 moles). The solution was stirred and 1-butanol was added until the total volume of 600.00 mL was achieved.

This precursor Barium titanate (BT) solution was spin coated in a clean room class 100 as per the following protocol:

The nickel foil had a bright surface finish (surface roughness RMS=40 nm) and nominal dimensions of 2″×2″×0.0015″. The foil metallurgical composition as per ICP analysis (by weight) was: <75 ppm Al, <25 ppm Ca, <700 ppm Fe, <85 ppm Mg, <1500 ppm Mn, all other possible impurities below 10 ppm.

The foil was cleaned prior to spin coating with water, then 2-propanol, then acetone. The spin coating conditions were: 750 μL/sublayer, 2000 rpm/30 secs, 10 sublayers. After spin coating of each precursor sublayer, the precursor sublayers were calcined at 150° C./5 min, then 400° C/15 mins

One final fire to crystallize the BT layer was executed, after all ten sublayers were deposited and calcined, using either conventional indirect IR heating lamps or the directly heated foil (DHF) technology. The comparative firing run, using indirect IR lamp heaters, was executed @1 mtorr of Ar flowing @80 sccm into a cryo-pumped stainless steel chamber. The DHF firing runs were executed @10 mtorr of Ar flowing @110 sccm into a cryo-pumped stainless steel chamber.

Atomic Force Microscopy analysis was carried out on the dielectric surface of the specimens. The atomic force microscope used a high resolution piezoelectric transducer to move a sharp microfabricated cantilever across the surface. Quantitative three-dimensional topographical images were generated as the probe tip responded to irregularities of the surface.

In Example 1, the indirect heating source was used. From room temperature, the coated foil was heated at 8° C./s to about 690° C., soaked for 30 mins, then cooled to room temperature with a maximum cooling rate of −40° C./s. Atomic force microscopy (AFM) analysis of the surface of the derived BT layer indicating that equiaxed grains with diameters up to roughly 10 nm were attained.

In Example 2, the coated foil was directly heated from room temperature at approximately 80° C./s to about 700° C., soaked for 30 mins, then cooled to room temperature with a maximum cooling rate of −200° C./s. The BT layer was very well adhered to the Ni substrate without any signs of delamination. AFM analysis of the surface of the derived BT layer indicating that equiaxed grains with diameters up to roughly 20 nm were attained.

In Example 3, the coated foil was directly heated from room temperature at approximately 120° C./s for 6 seconds, quenched to about 700° C. at <−150° C./s, soaked at about 700° C., soaked for 30 mins, then cooled to room temperature with a maximum cooling rate of −200° C./s. The BT layer was very well adhered to the Ni substrate without any signs of delamination. AFM analysis of the surface of the derived BT layer indicating that equiaxed grains with diameters up to roughly 60 nm were attained.

In Example 4, the coated foil was directly heated from room temperature at approximately 280° C./s to about 700° C., soaked for 30 mins and then cooled to room temperature with a maximum cooling rate of −200° C./s. The BT layer was very well adhered to the Ni substrate without any signs of delamination. AFM analysis of the surface of the derived BT layer indicating that equiaxed grains with diameters up to roughly 60 nm were attained.

In Example 5, the coated foil was directly heated from room temperature at approximately 80° C./s to about 700° C., soaked for 30 mins, then heated at about 280° C./s to about 1,000° C., soaked for 10 mins and then cooled to room temperature with a maximum cooling rate of −200° C./s. The BT layer was very well adhered to the Ni substrate without any signs of delamination. AFM analysis of the surface of the derived BT layer indicating that equiaxed grains with diameters up to roughly 100 nm were attained.

In Example 6, the coated foil was directly heated from room temperature at approximately 280° C./s to about 1,000° C., soaked for 10 mins and then cooled to room temperature with a maximum cooling rate of −200° C./s. The BT layer was very well adhered to the Ni substrate without any signs of delamination. AFM analysis of the surface of the derived BT layer indicating that equiaxed grains with diameters up to roughly 100 nm were attained.

What is claimed is:

1. A process comprising:
a) providing a metal foil substrate;
b) depositing a layer of solution comprising a Ti chelate, a Ba chelate and a solvent on the metal foil substrate;
c) passing an electric current through the metal foil substrate to evaporate the solvent and burn out the organic ligands chelated to Ti and the organic ligands chelated to Ba to form a residual layer;.
d) passing an electric current through the metal foil substrate to sinter the residual layer; and
e) depositing a top electrode on the surface of the sintered layer.

2. A process comprising:
a) providing a metal foil substrate;
b) vapor depositing a mixture comprising Ba and Ti oxides on the metal foil substrate;
c) passing an electric current through the metal foil substrate to heat the foil substrate to a temperature below the temperature of metal oxide formation during vapor deposition;
d) passing an electric current through the metal foil substrate to heat the foil substrate to a crystallization temperature for BaTiO3;
e) depositing a top electrode on the surface of the vapor deposited layer.
